(19) United States
(12) Patent Application Publication
(10) Pub. No.: US 2006/0066925 A1
(43) Pub. Date: Mar. 30, 2006

(54) Image forming apparatus, image processor, image processing method, and storage medium storing program

(75) Inventors: Noriko Hasegawa, Ebina-shi (JP); Hitoshi Ogatsu, Nakai-machi (JP); Toshio Koriyama, Ebina-shi (JP); Yasuki Yamauchi, Nakai-machi (JP); Toshifumi Takahira, Ebina-shi (JP)

Correspondence Address: OLIFF & BERRIDGE, PLC, P.O. BOX 19928, ALEXANDRIA, VA, 22320, US

(73) Assignee: FUJI XEROX CO., LTD., Tokyo (JP)

(21) Appl. No.: 11/078,491

(22) Filed: Mar. 14, 2005

(30) Foreign Application Priority Data
Sep. 27, 2004 (JP) 2004-279302

(51) Int. Cl. G03F 3/08

(52) U.S. Cl. 358/518

(57) ABSTRACT

An image forming apparatus includes an input unit that receives input of area designation information designating an image area to be subjected to color adjustment and adjustment amount information designating an adjustment amount of color adjustment, a color adjustment unit that performs color adjustment on rasterized image data in correspondence with the inputted area designation information and the adjustment amount information, and an image forming unit that forms an output image based on the image data subjected to the color adjustment by the color adjustment unit.

### BACKGROUND OF THE INVENTION

1. Field of the Invention

The present invention relates to image forming apparatus, for performing color adjustment on an image.

2. Description of the Related Art

For example, it is known to provide a color printer which refers to print data to determine the type of each object (figure, character, or photograph), selects a color correction table corresponding to the determined object type, and performs color correction on print data of the object based on the selected color correction table.

By this printer, when a user has visually checked a printed matter and determined to perform color correction, it is not necessary for the user to reselect DTP software or another application and perform color correction by object.

However, with this printer, a color correction coefficient applied to each object is fixed. For example, in a case where plural photographic objects exist in the same image, the same color adjustment is performed on these photographic objects. Thus appropriate color adjustment cannot be performed on the respective photographic images.

Accordingly, when color adjustment is independently performed on respective photographic images, it is necessary to reselect an application such as DTP software or image processing software.

Further, when color adjustment is performed by using an application such as DTP software or image processing software, adjustment cannot be performed as intended without knowledge of color adjustment by the application. Accordingly, in a case where an image to be printed includes plural types of images such as a photographic image, a character image and a computer graphic image (CG image), in order to perform color adjustment on a portion according to a photographic image, as an application for photograph adjustment is to be reselected, knowledge of photograph adjustment application is required. In order to perform color adjustment on a portion corresponding to a CG image, as a CG rendering application is reselected, knowledge of CG rendering application is required. That is, since it is necessary to reselect plural applications, knowledge of color adjustment by plural applications is required.

### SUMMARY OF THE INVENTION

The present invention has been made in view of the above-described background, and provides an image forming apparatus for performing color adjustment processing by each image area, which receives a request for color adjustment processing on a designated image area in laid-out image data, and performs color adjustment processing on the designated image area in correspondence with the request.

An aspect of the present invention is an image forming apparatus including: an input unit that receives input of area designation information designating an image area to be subjected to color adjustment and adjustment amount information designating an adjustment amount of color adjustment; a color adjustment unit that performs color adjustment on rasterized image data in correspondence with the inputted area designation information and the adjustment amount information; and an image forming unit that forms an output image based on the image data subjected to the color adjustment by the color adjustment unit.

### BRIEF DESCRIPTION OF THE DRAWINGS

Embodiments of the present invention will be described in detail based on the following figures, wherein:

FIG. 1 illustrates an example of the entire configuration of an image processing system 1;

FIG. 2 is a schematic cross-sectional diagram showing the configuration of a tandem-type printer 10;

FIG. 3 illustrates the hardware configuration of a client PC 4, mainly showing a controller 40, to which an image processing method according to the present invention is applied;

FIG. 4 is a block diagram showing the functional configuration of a print request program 5 executed by the client PC 4 (FIGS. 1 and 3) and the functional configuration of a print program 6 executed by the printer 10 (FIGS. 1 and 2);

FIG. 5 is an explanatory view of color conversion processing using a color adjustment layer 710;

FIG. 6 illustrates a top screen image 800 displayed on an UI unit 46;

FIGS. 7A and 7B illustrate color adjustment layers 710a and 710b for explaining generation of a new color conversion layer 710 using one template (color conversion layer stored in a color-conversion layout memory 640);

FIGS. 8A and 8B illustrate color adjustment layers 710a, 710c and 710d for explaining generation of a new color conversion layer 710 using plural templates (plural color conversion layers stored in the color-conversion layout memory 640);

FIG. 9A illustrates a color-conversion coefficient selection screen image 802;

FIG. 9B illustrates a color-adjustment setting screen image 804;

FIG. 10 is a flowchart showing printing processing (S10) in the image processing system 1; and

FIG. 11 illustrates a color adjustment layout database 642 stored in the color-conversion layout memory 640.

### DETAILED DESCRIPTION OF THE INVENTION

Hereinbelow, embodiments of the present invention will be described in accordance with the accompanying drawings.

First, the entire configuration of the image processing system 1 to which the present invention is applied will be described.

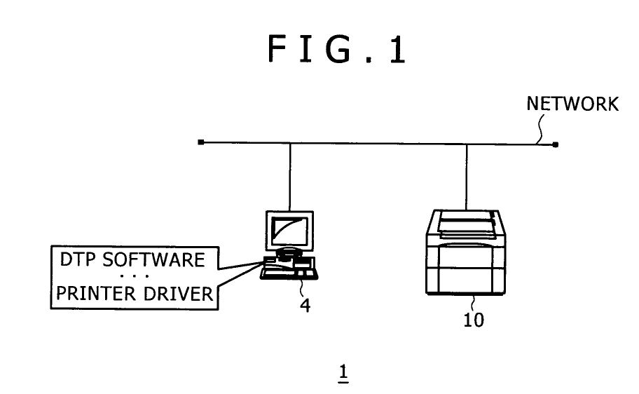

FIG. 1 illustrates an example of the entire configuration of the image processing system 1.

As shown in FIG. 1, the image processing system 1 has a client PC 4 and a tandem-type printer 10. The client PC 4 and the printer 10 are interconnected via a network such as a LAN or a WAN.

The client PC 4 is a general-purpose computer utilized by a user for image processing or the like. DTP software for image data editing or the like, a printer driver for print processing by the printer 10, and the like, are installed in the client PC 4.

Next, the printer 10 to which the present invention is applied will be described.

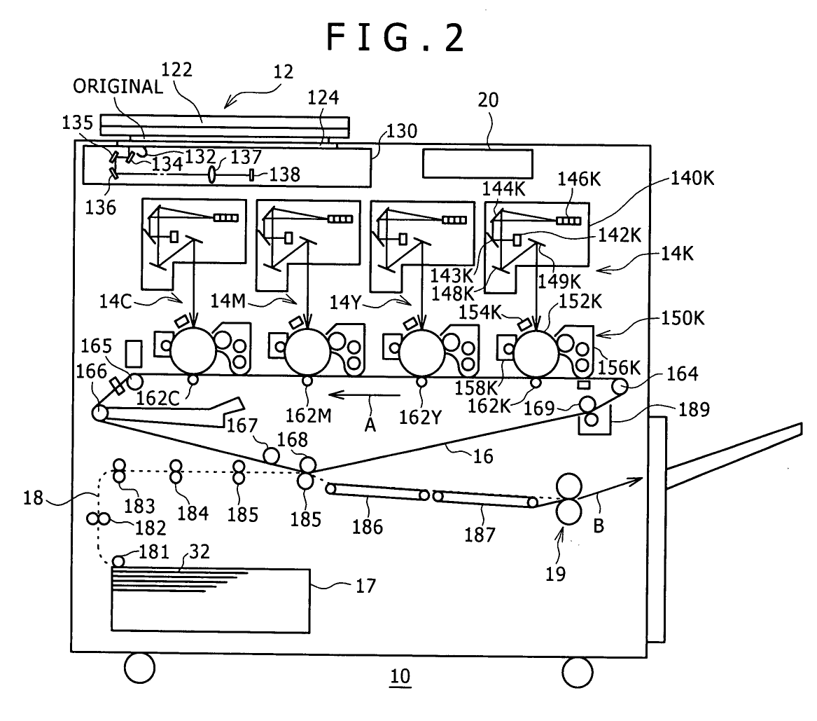

FIG. 2 is a schematic cross-sectional diagram showing the configuration of the tandem-type printer 10.

As shown in FIG. 2, the printer 10 has an image detecting unit 12, image forming units 14, an intermediate transfer belt 16, a paper tray 17, a paper transport passage 18, a fixing device 19 and an image processor 20. The printer 10 may be a multifunction machine having a full-color copying machine function using the image detecting unit 12 and a facsimile function, in addition to a printer function of printing image data received from the client PC 4 (FIG. 1).

First, the outline of the printer 10 will be described. The image detecting unit 12, which functions as image data input units, and the image processor 20 are provided in an upper part of the printer 10. The image detecting unit 12 detects an image of an original and outputs read image data to the image processor 20. The image processor 20 performs image processing such as color conversion, gradation correction and resolution correction on the image data inputted from the image detecting unit 12 or image data inputted from the client PC 4 or the like via the network such as a LAN (FIG. 1), and outputs the processed data to the image forming units 14.

The plural image forming units 14 are provided, in correspondence with colors constituting a color image, below the image detecting unit 12. In this embodiment, the image forming units, more specifically, first image forming unit 14K, second image forming unit 14Y, third image forming unit 14M and fourth image forming unit 14C, respectively corresponding to black (K), yellow (Y), magenta (M) and cyan (C), are horizontally arrayed at fixed intervals along the intermediate transfer belt 16. The intermediate transfer belt 16 rotates in an arrow A direction in the figure as an intermediate transfer medium. The four image forming units 14K, 14Y, 14M and 14C sequentially form toner images in the respective colors based on image data inputted from the image processor 20, and transfer the plural toner images at a predetermined timing to superpose them, onto the intermediate transfer belt 16 (primary transfer). The order of the respective image forming units 14K, 14Y, 14M and 14C is not limited to the above black (K), yellow (Y), magenta (M) and cyan (C), but any other order, e.g., yellow (Y), magenta (M), cyan (C) and black (K) may be set arbitrarily.

The paper transport passage 18 is provided below the intermediate transfer belt 16. A recording sheet 32, supplied from the paper tray 17, is transported on the paper transport passage 18. The plural color toner images superposed on the intermediate transfer belt 16 are transferred at once onto the recording sheet (secondary transfer), then the transferred toner images are fixed by the fixing device 19, and the recording sheet 32 is outputted along an arrow B to the outside.

Next, each unit of the printer 10 will be described in more detail.

As shown in FIG. 2, the image detecting unit 12 has a platen glass 124 on which the original is placed, a platen cover 122 to press the original against the platen glass 124, and an image detector 130 which detects an image of the original placed on the platen glass 124. The image detector 130 irradiates the original placed on the platen glass 124 with a light source 132, then scan-exposes an image detecting device 138 such as a CCD with a reflected light image from the original via a reduction optical system having a full rate mirror 134, a first half rate mirror 135, a second half rate mirror 136 and an image formation lens 137, and detects the color-material reflected light image of the original by the image detecting device 138 in a predetermined dot density (e.g., 16 dots/mm).

The image processor 20 performs predetermined image processing, including shading correction, original positional-shift correction, brightness/color space conversion, gamma correction, frame erasing, color/movement editing and the like, on image data detected by the image detecting unit 12. The original color-material reflected light image detected by the image detecting unit 12 is, e.g., 3-color (red (R), green (G) and blue (B) (of 8 bits each)) original reflectance data. The data is converted through the image processing by the image processor 20 into 4-color (yellow (Y), magenta (M), cyan (C) and black (K) (of 8 bits each)) original color-material gradation data.

The first image forming unit 14K, the second image forming unit 14Y, the third image forming unit 14M and the fourth image forming unit 14C (image forming unit) are arrayed in parallel at fixed intervals in a horizontal direction. The image forming units have substantially the same configuration except that colors constituting an image are different. Hereinbelow, the first image forming unit 14K will be described. The plural image forming units 14 in the figure are distinguished by adding alphabets K, Y, M and C.

The image forming unit 14K has an optical scanner 140K which emits laser beam in accordance with image data inputted from the image processor 20 and an image forming device 150K which forms an electrostatic latent image with the laser beam emitted by the optical scanner 140K.

The optical scanner 140K modulates a semiconductor laser 142K in correspondence with black (K) image data, and emits a laser beam LB(K) from the semiconductor laser 142K. The laser beam LB(K) emitted from the semiconductor laser 142K is applied on a polygonal rotating mirror 146K via a first reflecting mirror 143K and a second reflecting mirror 144K, then polarized by the polygonal rotating mirror 146K, and applied on a photoconductor drum 152K of the image forming device 150K via the second reflecting mirror 144K, a third reflecting mirror 148K and a fourth reflecting mirror 149K.

The image forming device 150K has the photoconductor drum 152K as an image carrier which rotates at a predetermined rotation speed along the arrow A direction, a scorotron charger 154K for primary charging as charging unit for uniformly charging the surface of the photoconductor drum 152K, a developing unit 156K which develops an electrostatic latent image formed on the photoconductor drum 152K, and a cleaner 158K. The photoconductor drum 152K is uniformly charged by the scorotron charger 154K, and an electrostatic latent image is formed on the drum surface with the laser beam LB(K) emitted from the optical scanner 140K. The electrostatic latent image formed on the photoconductor drum 152K is developed with black (K) toner by the developing unit 156K and transferred onto the intermediate transfer belt 16. Residual toner, paper powder and the like, attached to the photoconductor drum 152K after the process of toner image transfer, are removed by the cleaner 158K.

Similarly, the other image forming units 14Y, 14M and 14C form toner images in yellow (Y), magenta (M) and cyan (C), respectively, and transfer the color toner images onto the intermediate transfer belt 16.

The intermediate transfer belt 16 is placed around a drive roller 164, a first idle roller 165, a steering roller 166, a second idle roller 167, a backup roller 168 and a third idle roller 169, under predetermined tension. The intermediate transfer belt 16 is driven to move circularly at a predetermined speed in the arrow A direction by rotation drive of the drive roller 164 by a driving motor (not shown). The intermediate transfer belt 16 is an endless-shaped belt formed with a flexible synthetic resin film of polyimide or the like shaped in a belt, both ends of which are connected by welding or the like.

Further, the intermediate transfer belt 16 has a first primary transfer roller 162K, a second primary transfer roller 162Y, a third primary transfer roller 162M and a fourth primary transfer roller 162C in positions respectively corresponding to the image forming units 14K, 14Y, 14M and 14C. The plural color toner images formed on the photoconductor drums 152K, 152Y, 152M and 152C are superposingly-transferred onto the intermediate transfer belt 16 by these primary transfer rollers 162. Residual toner attached to the intermediate transfer belt 16 is removed by a cleaning blade or a brush of a belt cleaner 189 provided downstream of the secondary transfer position.

A paper feed roller 181 to pick up the recording sheet 32 from the paper tray 17, a pair of first rollers 181, a pair of second rollers 183 and a pair of third rollers 184, respectively for paper transport, and a registration roller 185 to transport the recording sheet 32 to the secondary transfer position at predetermined timing, are provided in the paper transport passage 18.

Further, a secondary transfer roller 185, in press-contact with the backup roller 168, is provided in the secondary transfer position on the paper transport passage 18. The color toner images superposingly-transferred on the intermediate transfer belt 16 are secondary-transferred onto the recording sheet 32 by press-contact force of the secondary transfer roller 185 and electrostatic force. The recording sheet 32, on which the color toner images are transferred, is transported by a first transport belt 186 and a second transport belt 187 to the fixing device 19.

The fixing device 19 performs heating processing and pressurization processing on the recording sheet 32 carrying the transferred color toner images, thereby fuses and fixes the toner to the recording sheet 32.

Next, the client PC 4 to which the present invention is applied will be described.

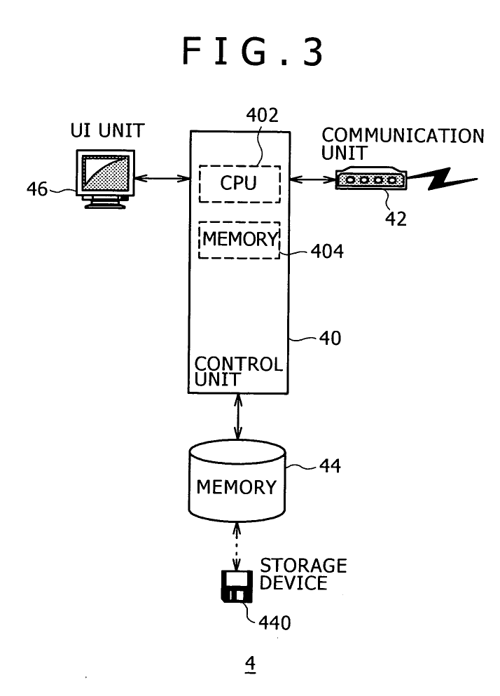

FIG. 3 illustrates the hardware configuration of the client PC 4, mainly showing the controller 40, to which an image processing method according to the present invention is applied.

As shown in FIG. 3, the client PC 4 has the controller 40 including a CPU 402, a memory 404 and the like, a communication unit 42, a memory 44 such as an HDD or CD, and a user interface (UI) unit 46 including an LCD device or CRT device, a keyboard, a touch panel and the like. The UI unit 46 is an example of an input unit.

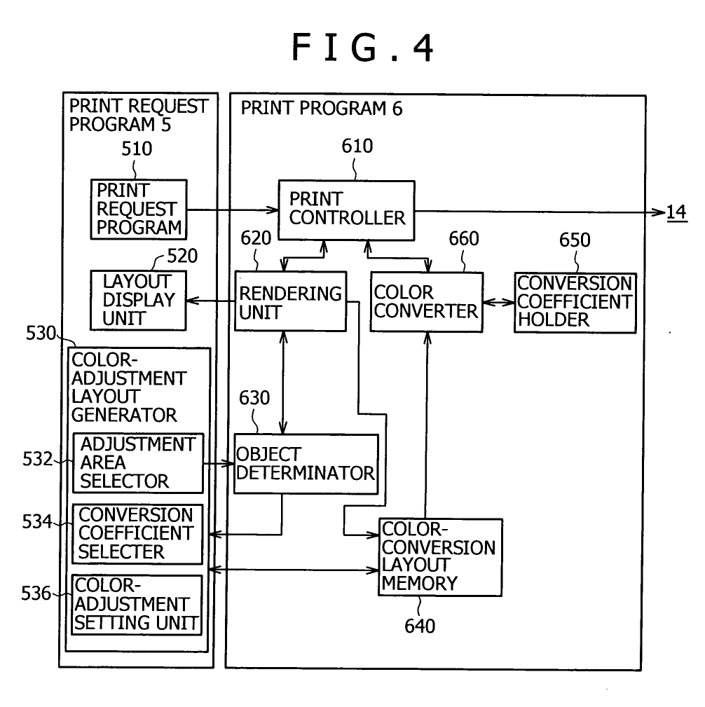

FIG. 4 is a block diagram showing the functional configuration of a print request program 5 executed by the client PC 4 (FIGS. 1 and 3) and the functional configuration of a print program 6 executed by the printer 10 (FIGS. 1 and 2).

As shown in FIG. 4, the print request program 5 has a print request unit 510, a layout display unit 520 and a color-adjustment layout generator 530. Further, the color-adjustment layout generator 530 includes an adjustment area selector 532, a conversion coefficient selector 534 and a color-adjustment setting unit 536. The print request program 5 is installed in the client PC 4.

Further, the print program 6 has a print controller 610, a rendering unit 620, an object determinator 630, a color-conversion layout memory 640, a conversion coefficient holder 650 and a color converter 660. The print program 6 is installed in the image processor 20 of the printer 10.

The print request program 5 and the print program 6 of this embodiment are realized as software, however, some or all the functions of the print program 5 may be implemented as hardware such as ASIC.

In the print request program 5, the print request unit 510 generates print request data in correspondence with the user's operation, and outputs the generated print request data to the print controller 610. The print request data includes image data of an input image as the subject of printing, data designating printing conditions such as the number of print copies, and the like. Further, the input image data is, e.g., a PDL file including plural objects.

The layout display unit 520 displays a layout image generated based on the input image data on the UI unit 46 (FIG. 3). The layout image is, an image where plural objects are arranged in correspondence with a rendering command such as a raster image (an image in which pixel groups are arranged by rasterization) generated based on a PDL file.

More specifically, the layout display unit 520 converts image data of a layout image (Lab color space image data inputted from the rendering unit 620), subjected to color compression processing in correspondence with the image output characteristic of an image output apparatus (printer 10 in this embodiment), using the ICC profile of the UI unit 46, to image data in output color space of the UI unit 46, and displays the data.

The user selects an image area (color adjustment area) to be subjected to color adjustment from the layout image displayed by the layout display unit 520.

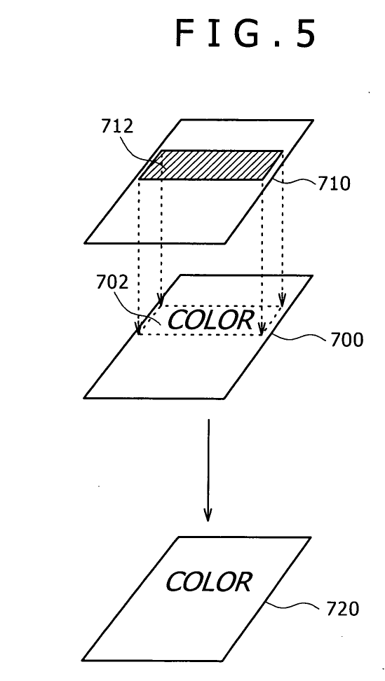

The color-adjustment layout generator 530 generates data of a color adjustment layer 710 as shown in FIG. 5, in correspondence with the user's operation, and outputs the generated data of the color adjustment layer 710 to the color-conversion layout memory 640.

FIG. 5 is an explanatory view of color conversion processing using the color adjustment layer 710.

As shown in FIG. 5, the color adjustment layer 710 is data including adjustment content information defining the content of color adjustment processing and area information,defining an area to be subjected to the color adjustment processing (color adjustment area 712), associated with each other. As shown in FIG. 5, the color adjustment layer 710 is represented as a layer overlapping an input image to be subjected to color adjustment processing (image layer 700). When the image layer 700 and the color adjustment layer 710 are inputted into the image output apparatus (printer 10), color adjustment processing is performed on the image layer 700 based on the color adjustment layer 710, and outputted as an output image 720.

More specifically, the adjustment area selector 532 selects an area to be subjected to color adjustment (color adjustment area) in correspondence with the user's operation, and notifies the object determinator 630 of the selected color adjustment area. The adjustment area selector 532 of this embodiment selects a color adjustment area from the layout image displayed by the layout display unit 520.

The conversion coefficient selector 534 selects a color conversion coefficient to be applied to the color adjustment area selected by the adjustment area selector 532 in correspondence with the user's operation, and associates the selected color conversion coefficient with the color adjustment area, as the color adjustment layer 710 (FIG. 5). The conversion coefficient selector 534 of this embodiment selects a color conversion coefficient by attribute of an object included in the selected color adjustment area. The color conversion coefficient is a coefficient to define color conversion processing (in this embodiment, conversion of Lab space image data to image data in the output color space (CMYK color space) of the printer). For example, the plural ICC profiles (plural profiles having different color reproduction) provided in the printer 10 are employed as color conversion coefficients.

The color-adjustment setting unit 536 sets color adjustment processing for the color adjustment area selected by the adjustment area selector 532 in correspondence with the user's operation, and associates the content of the set color adjustment processing with the color adjustment area as the color adjustment layer 710 (FIG. 5). The color-adjustment setting unit 536 sets the content of color adjustment processing by each attribute of an object included in the selected color adjustment area. The color adjustment processing is changing brightness, chroma, contrast, color balance and the like.

In the print program 6, the print controller 610 controls each of the units of the print program 6 in correspondence with print request data inputted from the print request unit 510 to generate print image data (CYMK image), and outputs the generated print image data (C image, M image, Y image and K image) to the respective image forming units 14 (FIG. 2).

The rendering unit 620 (data conversion unit) interprets image data (PDL file) of an input image in correspondence with the control by the print controller 610, and generates raster data. The generated raster data is, e.g., Lab color space image data.

Further, the rendering unit 620 converts the generated raster data, using the ICC profile of the printer 10, to image data corresponding to the color reproduction range of the printer 10 (at least image data subjected to color compression processing), and outputs the data to the layout display unit 520.

The object determinator 630 (attribute determination unit) determines an object (character image, photographic image, CG image the like) included in a color adjustment area selected by the adjustment area selector 532, and outputs the result of determination to the conversion coefficient selector 534 and the like.

The color-conversion layout memory 640 (adjustment result memory) associates the color adjustment layer 710 (FIG. 5) inputted from the color-adjustment layout generator 530 with the image layer 700 as the subject of color adjustment and stores the color adjustment layer 710.

Further, the color-conversion layout memory 640 outputs the stored color adjustment layer 710, as a template, to the color-adjustment layout generator 530.

In this embodiment, the color-conversion layout memory 640 is provided on the printer (print program 6) side, however, the present invention is not limited to this configuration, and the color-conversion layout memory 640 may be provided on the client PC (print request program 5) side, and the color adjustment layer 710 may be stored on the client PC side.

The conversion coefficient holder 650 (correction coefficient determination unit) determines a color conversion coefficient based on the color adjustment layer 710 (FIG. 5), and stores the determined color conversion coefficient. The stored color conversion coefficient is associated with an input image to be subjected to color conversion, an area to be subjected to the color conversion, and an object attribute to be subjected to the color conversion.

The color converter 660 (color correction unit) converts input image data (the Lab color-space image data in this embodiment), using the color conversion coefficient stored by the conversion coefficient holder 650, to image data in the color space (CMYK color space) of the printer 10. More specifically, the color converter 660 performs color conversion processing using a color conversion coefficient associated with a subject area (color adjustment area or the like) and an attribute of an object while selecting the color conversion coefficient in correspondence with the subject area and the attribute of the object. By this processing, an output image 720 (FIG. 5) where color adjustment has been performed based on the color adjustment layer 710 is generated.

Next, an input screen image displayed on the client PC 4 will be described.

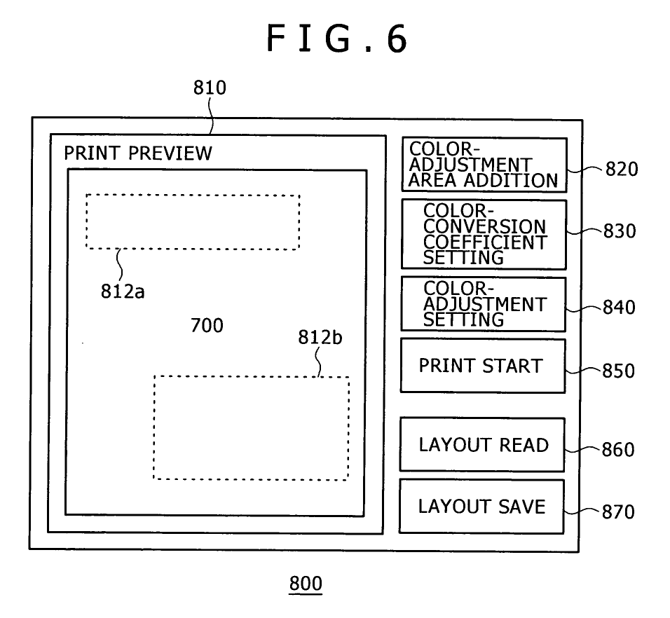

FIG. 6 illustrates a top screen image 800 displayed on the UI unit 46.

As shown in FIG. 6, the top screen image 800 includes a preview area 810 to display the input image 700 or the like, a color-adjustment area addition button 820 to perform selection of a color adjustment area, a color-conversion coefficient setting button 830 to perform setting of a color conversion coefficient, a color adjustment setting button 840 to perform setting of color adjustment, a print start button 850 to designate print start, a layout read button 860 to perform reading the color adjustment layer 710, and a layout save button 870 to store the generated color adjustment layer 710.

The preview area 810 is an area displayed by the layout display unit 520 (FIG. 4), in which a layout image corresponding to the input image 700 (input image subjected to color gamut compression in correspondence with the color reproduction range of the printer 10) is displayed. Further, when a color adjustment area is selected in the layout image, an area display 812 showing the selected color adjustment area is displayed on the layout image. In this embodiment, as two color adjustment areas are selected, two area displays 812 are displayed.

Further, when storage of the color adjustment layer 710 is requested, the input image 700 subjected to color adjustment based on the color adjustment layer 710 is displayed in the preview area 810. More particularly, when the layout save button 870 has been clicked, the print program 6 stores the color adjustment layer 710, performs color conversion on the input image 700 based on the color adjustment layer 710 (i.e., performs color adjustment processing corresponding to the color adjustment layer 710), converts the input image 700 (CMYK image) subjected to the color conversion processing to image data in device-independent color space (Lab image), and outputs the image data to the layout display unit 520 of the print request program 5. The layout display unit 520 displays the input image 700 subjected to the color adjustment processing in the preview area 810 based on the image data.

The color-adjustment area addition button 820, which is an operation area displayed by the adjustment area selector 532, is used for reception of a color-adjustment area addition request. When the color-adjustment area addition button 820 has been clicked, an area selection operation is enabled in the preview area 810, and the adjustment area selector 532 detects an area selection operation and adds a color adjustment area in correspondence with the result of detection.

The color-conversion coefficient setting button 830, which is an operation area displayed by the conversion coefficient selector 534, is used for reception of color-conversion coefficient setting request. When the color-conversion coefficient setting button 830 has been clicked, the conversion coefficient selector 534 displays a color-conversion coefficient selection screen image 802 (to be described later).

The color adjustment setting button 840, which is an operation area displayed by the color adjustment setting unit 536, is used for reception of color-adjustment setting request. When the color adjustment setting button 840 has been clicked, the color adjustment setting unit 536 displays a color-adjustment coefficient selection screen image 802 (to be described later).

The print start button 850 is used for reception of a print start instruction.

The layout read button 860, which is an operation area displayed by the color-adjustment layout generator 530, is used for reception of a request for reading of the color adjustment layer 710 stored in the color-conversion layout memory 640. When the layout read button 860 has been clicked, the color-adjustment layout generator 530 reads data of a desired color adjustment layer 710 from the color-conversion layout memory 640, and displays the read color adjustment layer 710 as a template.

The layout save button 870, which is an operation area displayed by the color-adjustment layout generator 530, is used for reception of a request for storage of color adjustment layer 710 data. When the layout save button 870 has been clicked, the color-adjustment layout generator 530 stores data of the generated color adjustment layer 710 into the color-conversion layout memory 640.

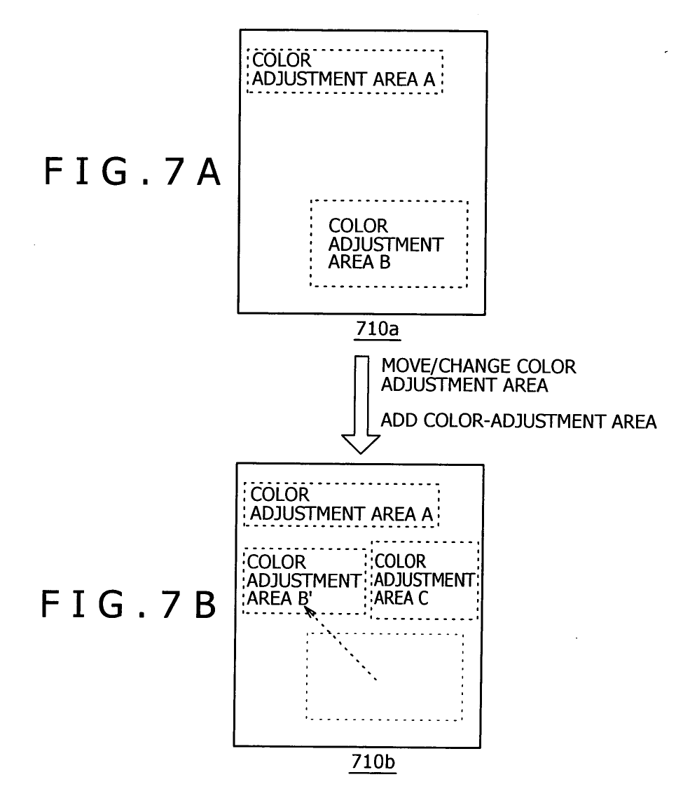

FIGS. 7A and 7B illustrate color adjustment layers 710a and 710b for explaining generation of a new color conversion layer 710 using one template (color conversion layer stored in the color-conversion layout memory 640).

When the layout read button 860 (FIG. 6) has been clicked, the color adjustment layer 710a stored in the color-conversion layout memory 640 is read and displayed as shown in FIG. 7A. In this embodiment, two color adjustment areas (color adjustment area A and color adjustment area B) are set in the color adjustment layer 710a. The contents of color adjustment processing for the respective color adjustment areas can be browsed by operating the color-conversion coefficient setting button 830 or the color adjustment setting button 840.

The user can change the position, shape and size of color adjustment area included in a template by dragging the color adjustment area. In this embodiment, as shown in FIG. 7B, the color adjustment area B included in the template is changed to a color adjustment area B′. In correspondence with this operation, the color-adjustment layout generator 530 updates the position, shape and size of the color adjustment area of the template (color adjustment layer) read from the color-conversion layout memory 640. Further, the contents of the color adjustment processing set for the respective color adjustment areas (color conversion coefficients or the like) can be changed by operating the color-conversion coefficient setting button 830 or the color adjustment setting button 840.

Further, the user can add a new color adjustment area (color adjustment area C in this embodiment) to the template by clicking the color-adjustment area addition button 820.

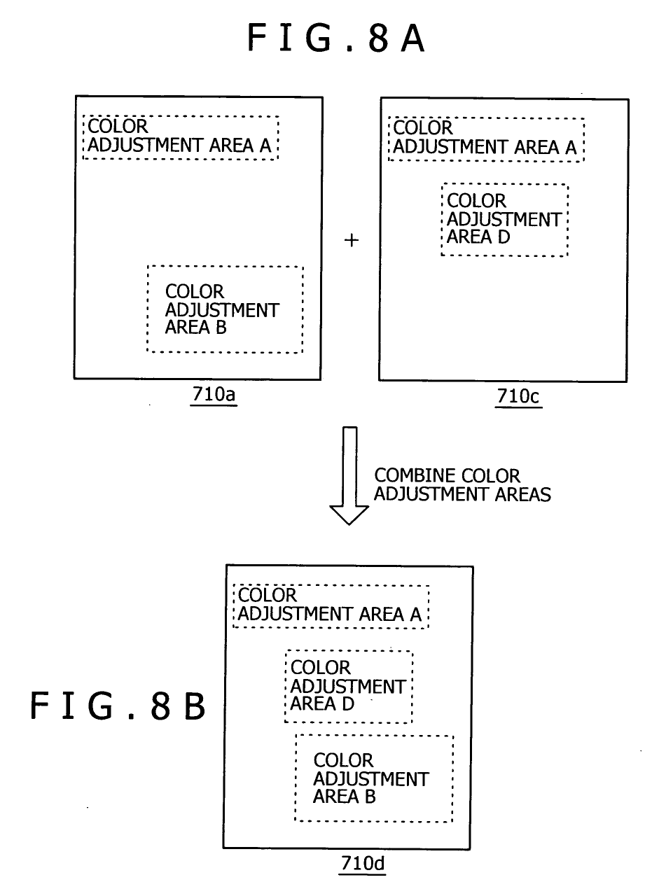

FIGS. 8A and 8B illustrate color adjustment layers 710a, 710c and 710d for explaining generation of a new color conversion layer 710 using plural templates (plural color conversion layers stored in the color-conversion layout memory 640).

For example, when the layout read button 860 (FIG. 6) has been clicked to designate two color adjustment layers 710 (color adjustment layer 710a and color adjustment layer 710c), two color adjustment layers 710 (color adjustment layer 710a and color adjustment layer 710c) stored in the color-conversion layout memory 640 are read as shown in FIG. 8A, and displayed as templates in different windows.

When the user designates combining of these templates (color adjustment layers 710), the color-adjustment layout generator 530 obtains the sum-set of color adjustment areas included in these templates, and generates a new color adjustment layer 710d. In this embodiment, as shown in FIG. 8B, a color adjustment area A and a color adjustment area B included in the first color adjustment layer 710a are combined with a color adjustment area A and a color adjustment area D included in the second color adjustment layer 710c, thereby the color adjustment layer 710d including the color adjustment area A, the color adjustment area B and the color adjustment area D is generated. The color-adjustment layout generator 530 may generate a color adjustment layer 710 of overlap portion (product set) of color adjustment areas 710 based on plural templates.

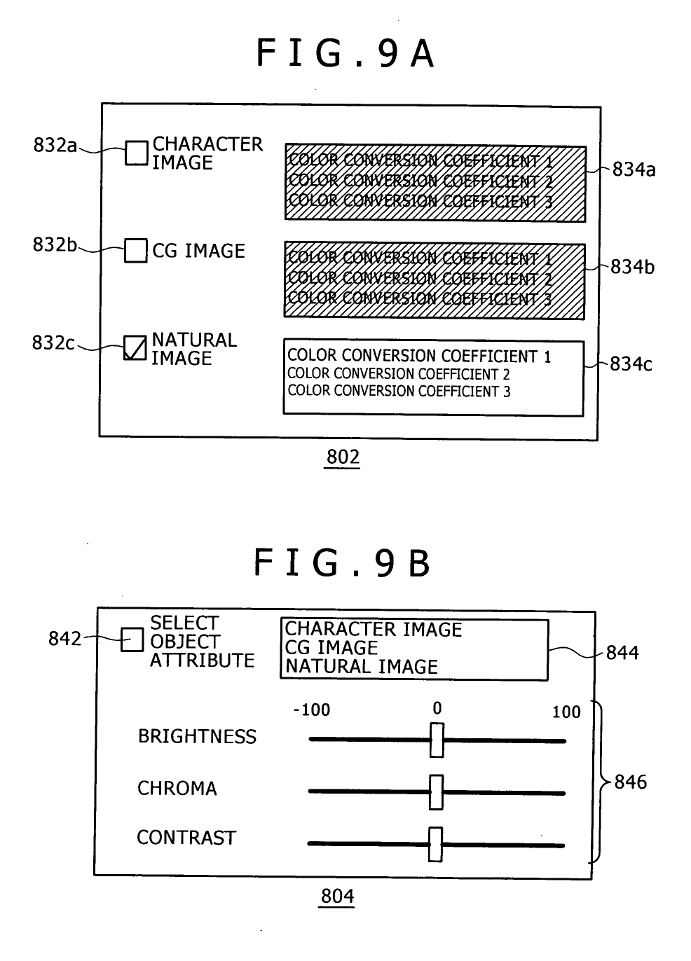

FIG. 9A illustrates the color-conversion coefficient selection screen image 802. FIG. 9B illustrates the color-adjustment setting screen image 804.

In a state where any of the area displays 812 is active (selected) in the preview area 810 (FIG. 6), when the color-conversion coefficient setting button 830 has been clicked, the color-conversion coefficient selection screen image 802 is displayed as shown in FIG. 9A for setting of a color conversion coefficient for the color adjustment area corresponding to the area display 812. The color-conversion coefficient selection screen image 802 includes check boxes 832 to select the attribute of object (character image, natural (photographic) image, CG image and the like), and coefficient selection areas 834 to select color conversion coefficients to be applied to the respective object attributes. When the user checks one of the check boxes 832 corresponding to a desired object attribute, one of the coefficient selection areas 834 to select a color conversion coefficient of the object attribute becomes active, thus selection of a color conversion coefficient is enabled.

The conversion coefficient selector 534 detects the operations to the check box 832 and the coefficient selection area 834, and selects a color conversion coefficient corresponding to each color adjustment area.

In a state where any of the area displays 812 is active in the preview area 810 (FIG. 6), when the color adjustment setting button 840 has been clicked, the color-adjustment setting screen image 804 is displayed as shown in FIG. 9B for setting of the content of color adjustment to the color adjustment area corresponding to the selected area display 812. The color-adjustment setting screen image 804 includes a check box 842 to designate execution/non-execution of selection of an object attribute, an attribute selection area 844 to receive selection of the object attribute, and slider bars 846 to designate change amounts of brightness, chroma, contrast and the like.

When the check box 842 is checked, selection of the object attribute in the attribute selection area 844 is enabled, while, when the checked state of the check box 844 is released, all the object attributes included in a selected color adjustment area come into a selected state. That is, when the checked state of the check box 844 is released, object attributes determined by the object determinator 630 come into a selected state in the attribute selection area 844.

The slider bars 846 corresponding to brightness, chroma and contrast are used for reception of designated color adjustment amounts to a selected object attribute in a selected color adjustment area.

The color adjustment setting unit 536 sets adjustment amounts of brightness, chroma and contrast for each object attribute included in the color adjustment area, in correspondence with the user's operation in the color-adjustment setting screen image 804.

Next, the operations of the print request program 5 and the print program 6 will be described.

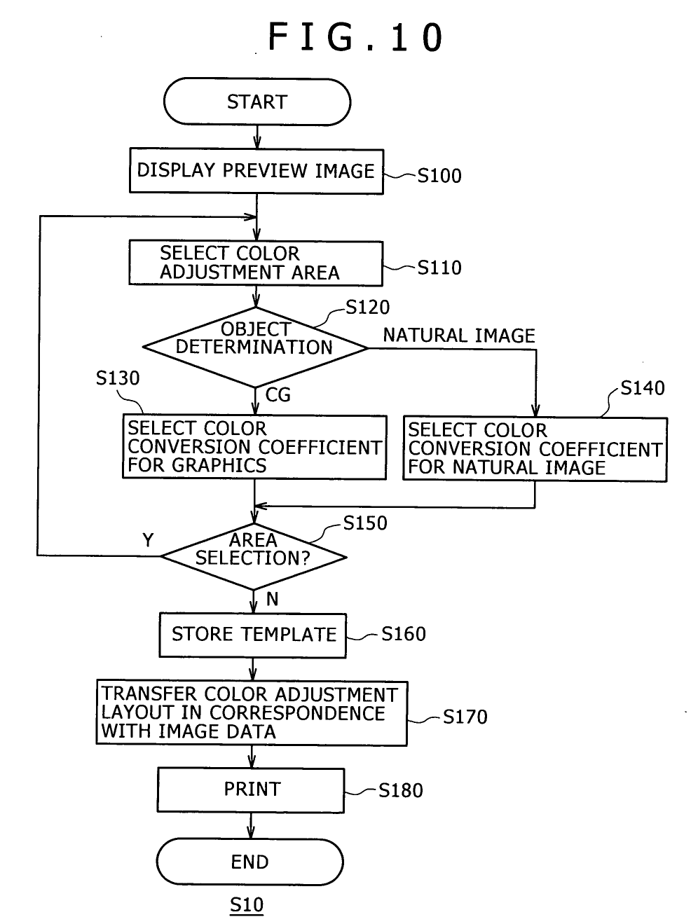

FIG. 10 is a flowchart showing printing processing (S10) in the image processing system 1.

As shown in FIG. 10, at step S100, the print request unit 510 of the print request program 5 (FIG. 4) outputs print request data including a PDL file (input image) to the print controller 610 of the print program 6.

The print controller 610 transfers the PDL file to the rendering unit 620 and instructs to generate a preview image.

The rendering unit 620 interprets the PDL file transferred from the print controller 610, generates raster data of the input image, and outputs the generated raster data to the print controller 610, the object determinator 630 and the color-conversion layout memory 640. Further, the rendering unit 620 performs color compression processing corresponding to the color reproduction range of the printer 10 on the generated raster data of the input image, and outputs the color-compression processed image data, as preview image data, to the layout display unit 520.

The layout display unit 520 generates image data for preview display, using the ICC profile of the UI unit 46, based on the raster data of the input image inputted from the rendering unit 620, and displays the image in the preview area 810 (FIG. 6).

At step S110, the user clicks the color-adjustment area addition button 820 (FIG. 6), then selects the range of a color adjustment area in the preview area 810.

The adjustment area selector 532 detects the user's operation, selects a color adjustment area, and outputs the selected color adjustment area to the object determinator 630.

At step S120, the object determinator 630 determines the attribute of an object included in the color adjustment area selected by the adjustment area selector 532 based on the image data of the input image inputted from the rendering unit 620, and outputs the result of attribute determination to the color-adjustment layout generator 530 and the rendering unit 620. The result of attribute determination outputted to the rendering unit 620 is inputted into the color converter 660 via the print controller 610, and used for specifying the attribute of object in color conversion processing.

If a CG image (including a character image in the flowchart) is included in the selected color adjustment area, the print request program 5 proceeds to processing at step S130, while, if a natural image (photographic image or the like) is included in the selected color adjustment area, the print request program 5 proceeds to processing at step S140. If both CG image and natural image are included in the color adjustment area, the processing at step S130 and the processing at step S140 are performed.

At step S130, when the color-conversion coefficient setting button 830 (FIG. 6) has been clicked, the conversion coefficient selector 534 displays the color-conversion coefficient selection screen image 802 (FIG. 9A), to receive selection of color conversion coefficient to be applied to the CG image, and associates the selected color conversion coefficient with the color adjustment area and the object attribute (CG image).

Further, when the color adjustment setting button 840 (FIG. 6) has been clicked, the color adjustment setting unit 536 displays the color-adjustment setting screen image 804 (FIG. 9B), to receive designation of the contents of color adjustment processing (change of brightness, change of chroma and change of contrast) to be applied to the CG image, and associates the designated content of color adjustment processing with the color adjustment area and the object attribute (CG image).

At step S140, when the color-conversion coefficient setting button 830 (FIG. 6) has been clicked, the conversion coefficient selector 534 displays the color-conversion coefficient selection screen image 802 (FIG. 9A), to receive selection of a color conversion coefficient to be applied to the natural image, and associates the selected color conversion coefficient with the color adjustment area and the object attribute (natural image).

Further, when the color adjustment setting button 840 (FIG. 6) has been clicked, the color adjustment setting unit 536 displays the color-adjustment setting screen image 804 (FIG. 9B), to receive designation of the contents of color adjustment processing (change of brightness, change of chroma and change of contrast) to be applied to the natural image, and associates the designated content of color adjustment processing with the color adjustment area and the object attribute (natural image).

At step S150, the color-adjustment layout generator 530 stands by until the layout save button 870 (FIG. 6) has been clicked or the color-adjustment area addition button 820 (FIG. 6) has been clicked. When the layout save button 870 has been clicked, the color-adjustment layout generator 530 proceeds to processing at step S160, while, when the color-adjustment area addition button 820 has been clicked, returns to the processing at step S110.

At step S160, the color-adjustment layout generator 530 generates a color adjustment layer 710 (FIG. 5) based on the color conversion coefficient or the contents of color adjustment processing associated with the color adjustment area and the object attribute, and stores the data of the generated color adjustment layer 710 into the color-conversion layout memory 640.

The color-conversion layout memory 640 associates the color conversion layer 710 inputted from the color-adjustment layout generator 530 with the image data of the input image (image layer 700 (FIG. 5)) and stores the color conversion layer 710.

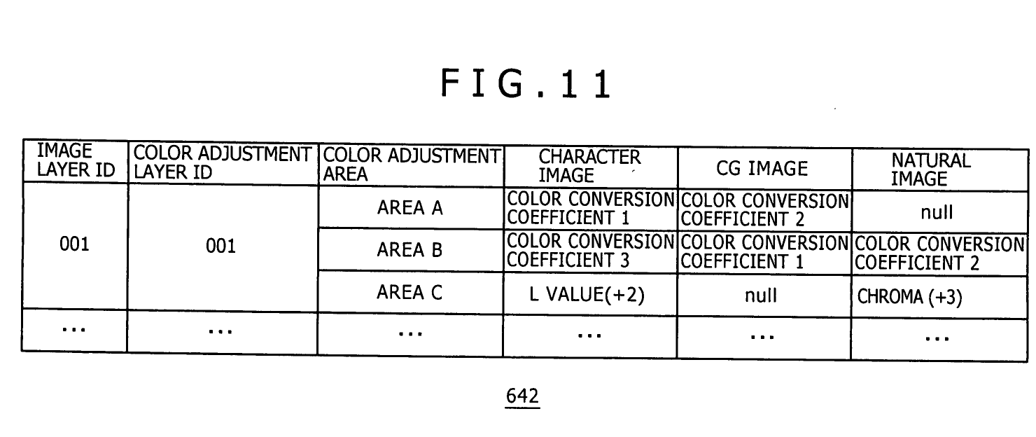

FIG. 11 illustrates a color adjustment layout database 642 stored in the color-conversion layout memory 640.

As shown in FIG. 11, the color conversion layer 710 inputted from the color-adjustment layout generator 530, associated with the image data of the input image (image layer 700), is registered in the color adjustment layout database (DB) 642. In one color adjustment layer, at least one color adjustment area is set. Regarding each color adjustment area, a color conversion coefficient (e.g. conversion coefficient 1) or contents of color adjustment processing corresponding to the object attribute are set.

At step S170, the color converter 660 reads the color adjustment layer 710 corresponding to the input image as the subject of printing from the color-conversion layout memory 640, and determines a color conversion coefficient based on the read color adjustment layer 710, and stores the determined color conversion coefficient into the conversion coefficient holder 650.

The color converter 660 refers to the color conversion coefficient (associated with the color adjustment area and the object attribute) stored in the conversion coefficient holder 650, and converts the image data of the input image, using the color conversion coefficient corresponding to the image area and the object attribute, to image data for printing (CMYK image).

At step S180, the print controller 610 converts the image data (CMYK image) color-converted by the color converter 660, using the ICC profile of the printer 10, to image data in device-independent color space (Lab image), and outputs the image data (Lab image) to the layout display unit 520.

The layout display unit 520 converts the image data (Lab image inverse-converted from the CMYK image), using the ICC profile of the UI unit 46, to image data for display (RGB image), and displays the image as a preview image (image subjected to color adjustment processing).

When the user clicks the print start button 850 (FIG. 6), the print controller 610 transfers the image data (CMYK image) color-converted by the color converter 660 to the image forming units 14. Then the image data subjected to the color adjustment is print-outputted on a recording sheet.

As described above, in the image processing system 1 according to this embodiment, as color adjustment is performed on laid-out image data (after RIP), color adjustment can be made by image area included in a document. In this configuration, even in a case where similar colors exist in different portions of the same document (input image), color adjustment can be performed on only a target object without shifting the colors.

Further, in the image processing system 1, as a color adjustment area as the subject of color adjustment is designated, color adjustment of an object can be performed on laid-out image data without reselecting DTP software.

Further, in the image processing system 1, color adjustment is performed on laid-out image data, color adjustment setting information (color adjustment layer) is stored, and stored color adjustment setting information (color adjustment layer(s)) is edited or combined. Thus color adjustment setting processing is facilitated. In this configuration, even if a user does not have knowledge of color adjustment by an application such as DTP software, the user can perform color adjustment similar to that by a user having knowledge of color adjustment by using stored color adjustment layer.

As described above, according to an aspect of the present invention, an image forming apparatus includes an input unit that receives input of area designation information designating an image area to be subjected to color adjustment and adjustment amount information designating an adjustment amount of color adjustment, a color adjustment unit that performs color adjustment on rasterized image data in correspondence with the inputted area designation information and the adjustment amount information, and an image forming unit that forms an output image based on the image data subjected to the color adjustment by the color adjustment unit.

According to another aspect of the present invention, the image forming apparatus may further include a data conversion unit that converts inputted image data to raster data corresponding to output color space reproduced by the image forming unit, and the input unit displays an image based on the raster data converted by the data conversion unit, and receives the area designation information and the adjustment amount designation information for color adjustment on the displayed image.

According to another aspect of the present invention, the color adjustment unit may perform color adjustment by attribute of an object in an image area corresponding to the inputted area designation information.

According to another aspect of the present invention, the adjustment amount designation information may include information designating a content of color adjustment by attribute of an object, and the color adjustment unit includes: a correction coefficient determination unit that determines a color correction coefficient corresponding to an attribute of an object, based on inputted adjustment amount designation information, by image area corresponding to inputted area designation information; an attribute determination unit that determines an attribute of an object in each image area corresponding to the area designation information; and a color correction unit that performs color correction on image data of the object using a color correction coefficient corresponding to the attribute determined by the attribute determination unit and the image area.

According to another aspect of the present invention, the image forming apparatus may further include an adjustment result memory that associates a content of color adjustment by the color adjustment unit with the image area subjected to the color adjustment and stores the content of color adjustment and the image area.

Further, according to another aspect of the present invention, an image processor includes an input unit that receives input of area designation information designating an image area to be subjected to color adjustment and adjustment amount information designating an adjustment amount of color adjustment, and a color adjustment unit that performs color adjustment on rasterized image data in correspondence with the inputted area designation information and the adjustment amount information.

According to another aspect of the present invention, an image processing method includes receiving input of area designation information designating an image area to be subjected to color adjustment and adjustment amount information designating an adjustment amount of color adjustment, and performing color adjustment on rasterized image data in correspondence with the inputted area designation information and the adjustment amount information.

According to another aspect of the present invention, a storage medium readable by a computer in an image processor, the storage medium storing a program of instructions executed by the computer to perform a function includes receiving input of area designation information designating an image area to be subjected to color adjustment and adjustment amount information designating an adjustment amount of color adjustment, and a performing color adjustment on rasterized image data in correspondence with the inputted area designation information and the adjustment amount information.

According to the image processor of the present invention, color adjustment processing can be performed by image area.

While this invention has been described in connection with certain embodiments, it is to be understood that the subject matter encompassed by way of this invention is not to be limited to those specific embodiments. On the contrary, it is intended for the subject matter of the invention to include all alternative, modification and equivalents as can be included within the spirit and scope of the following claims.

The entire disclosure of Japanese Patent Application No. 2004-279302 filed on Sep. 27, 2004 including specification, claims, drawings and abstract is incorporated herein by reference in its entirety.

1. An image forming apparatus comprising:
an input unit that receives input of area designation information designating an image area to be subjected to color adjustment and adjustment amount information designating an adjustment amount of color adjustment;
a color adjustment unit that performs color adjustment on rasterized image data in correspondence with the inputted area designation information and the adjustment amount information; and
an image forming unit that forms an output image based on the image data subjected to the color adjustment by the color adjustment unit.

2. The image forming apparatus according to claim 1, further comprising a data converter that converts inputted image data to raster data corresponding to output color space reproduced by the image forming unit,
wherein the input unit displays an image based on the raster data converted by the data converter, and receives the area designation information and the adjustment amount information for color adjustment on the displayed image.

3. The image forming apparatus according to claim 1, wherein the color adjustment unit performs color adjustment by each attribute of an object in an image area corresponding to the inputted area designation information.

4. The image forming apparatus according to claim 1, wherein the adjustment amount information includes information designating a content of color adjustment by each attribute of an object, and
wherein the color adjustment unit includes:
a correction coefficient determination unit that determines a color correction coefficient corresponding to an attribute of an object, based on inputted adjustment amount information, by each image area corresponding to inputted area designation information;
an attribute determination unit that determines an attribute of an object in each image area corresponding to the area designation information; and
a color correction unit that performs color correction on image data of the object using a color correction coefficient corresponding to the attribute determined by the attribute determination unit and the image area.

5. The image forming apparatus according to claim 1, further comprising an adjustment result memory that associates a content of color adjustment by the color adjustment unit with the image area subjected to the color adjustment and stores the content of color adjustment and the image area.

6. An image processor comprising:
an input unit that receives input of area designation information designating an image area to be subjected to color adjustment and adjustment amount information designating an adjustment amount of color adjustment; and
a color adjustment unit that performs color adjustment on rasterized image data in correspondence with the inputted area designation information and the adjustment amount information.

7. An image processing method comprising:
receiving input of area designation information designating an image area to be subjected to color adjustment and adjustment amount information designating an adjustment amount of color adjustment; and
performing color adjustment on rasterized image data in correspondence with the inputted area designation information and the adjustment amount information.

8. A storage medium readable by a computer in an image processor, the storage medium storing a program of instructions executed by the computer to perform a function comprising:
receiving input of area designation information designating an image area to be subjected to color adjustment and adjustment amount information designating an adjustment amount of color adjustment; and
performing color adjustment on rasterized image data in correspondence with the inputted area designation information and the adjustment amount information.
